(19) United States
(12) Patent Application Publication
(10) Pub. No.: US 2010/0088051 A1
(43) Pub. Date: Apr. 8, 2010

(54) ELECTRONIC DEVICE, BATTERY, AND BATTERY REMAINING CAPACITY DISPLAY METHOD

(75) Inventors: Toshio Iwai, Osaka (JP); Toshiyuki Okamura, Hyogo (JP); Katsuhiro Yokoyama, Osaka (JP); Hiroki Takahara, Osaka (JP); Osamu Ohashi, Osaka (JP)

Correspondence Address: HAMRE, SCHUMANN, MUELLER & LARSON P.C., P.O. BOX 2902-0902, MINNEAPOLIS, MN, 55402, US

(73) Assignee: PANASONIC CORPORATION, Kadoma-shi, Osaka (JP)

(21) Appl. No.: 12/516,451

(22) PCT Filed: Nov. 27, 2007
(86) PCT No.: PCT/JP2007/072835

§ 371 Date: May 27, 2009

(30) Foreign Application Priority Data
Nov. 30, 2006 (JP) 2006-323432

(51) Int. Cl. G01R 31/36; H02J 7/00; G08B 21/00

(52) U.S. Cl. 702/63; 320/132; 340/636.1

(57) ABSTRACT

The present invention provides an electronic device capable of displaying a remaining capacity of a battery 1 that includes a battery microcomputer 2 capable of outputting battery information including remaining capacity information. The device includes: a main body microcomputer 4 that obtains the battery information from the battery microcomputer 2, and calculates a remaining capacity actual value representing an actual remaining capacity of the battery 1 based on the battery information; and a display portion 5 that displays the remaining capacity of the battery 1 under the control of the main body microcomputer 4. The main body microcomputer 4 subtracts a correction margin value representing an individual difference of the battery 1 from the remaining capacity actual value so as to calculate a remaining capacity correction value, and controls the display portion 5 so as to display a remaining capacity of zero for a region where the remaining capacity correction value is equal to or smaller than the correction margin value. Therefore, it is possible to provide an electronic device in which a remaining capacity display value decreases properly with the passage of actual time.

### TECHNICAL FIELD

The present invention relates to an electronic device and a battery having the capability of displaying a battery remaining capacity. Further, the present invention relates to a battery remaining capacity display method for displaying the remaining capacity in an electronic device or a battery.

### BACKGROUND ART

In recent years, battery-operated electronic devices such as a digital camera and a video camera often have the capability of displaying a remaining capacity of a battery. The remaining capacity of the battery is displayed on a liquid crystal monitor mounted on an electronic device in the form of a mark that changes shape in accordance with the remaining capacity of the battery or in terms of a lifetime calculated based on the remaining capacity of the battery. In the case of displaying the battery remaining capacity in terms of a lifetime, a current during the charging and discharging of the battery is integrated, and the lifetime is calculated based on the current integrated value. However, this calculation method often leads to an error between the current integrated value and an actual remaining capacity of the battery, which then results in an error between the calculated lifetime and a lifetime based on the actual battery remaining capacity. Patent Document 1 discloses a technique of correcting the integration error caused by the current integration technique by using a remaining capacity of the battery obtained from a voltage.

FIG. 8 shows an example of an electronic device having the capability of displaying a battery remaining capacity. As shown in FIG. 8, a battery 21 has a battery microcomputer 22. The battery microcomputer 22 processes information from the battery. An electronic device 23, which is a battery-powered device such as a digital camera and a video camera, is in this configuration a video camera, for example. The electronic device 23 has a main body microcomputer 24. The main body microcomputer 24 obtains the information on the battery 21 from the battery microcomputer 22 via a communication line, and calculates a lifetime of the battery 21. A display control portion 26 stores a result of calculating the remaining capacity by the main body microcomputer 24, and displays the remaining capacity in a display portion 25 based on the result of calculating the remaining capacity. The display portion 25 displays at least the result of calculating the remaining capacity under the control of the display control portion 26. The remaining capacity is displayed in terms of a lifetime expressed numerically (in minutes), for example.

FIG. 9A shows a change in a current integrated capacity value with the passage of time during the charging of the battery 21. FIG. 9B shows a change in a current integrated capacity value with the passage of time during the discharging of the battery 21. In FIGS. 9A and 9B, the vertical axis represents the current integrated capacity value, and the horizontal axis represents the passage of time. When the battery 21 is charged with a constant current, the current integrated capacity value increases in direct proportion to the passage of time as shown in FIG. 9A. When the battery is fully charged, the charging operation is stopped under the control of a battery charger or the like. On the other hand, when the battery 21 is discharged with a constant current, the current integrated capacity value decreases in inverse proportion to the passage of time as shown in FIG. 9B. When the battery 21 is fully discharged, the battery microcomputer 22 instructs the electronic device 23 to turn off a power source. Based on the instruction from the battery 21, the electronic device 23 stops the operation. Accordingly, consumption of the current integrated capacity of the battery 21 is stopped, and overdischarge is prevented.

In general, in the method of using the current integrated capacity, the capacity is obtained through a constant monitoring of a current flowing into the battery 21 per unit time or a current flowing out of the battery 21 per unit time. More specifically, during charging, a current (mA) flowing into a cell of the battery 21 per unit time is added sequentially to the current integrated capacity (mAh) per unit time, and an increase in the current integrated capacity is managed. During discharging, on the other hand, a current (mA) flowing out of the cell of the battery 21 per unit time is subtracted sequentially from the current integrated capacity (mAh) per unit time, and a decrease in the current integrated capacity is managed.

However, the detection accuracy of a current and the accuracy of a unit time during measurement are affected by variations of electrical components used in the electronic device 23, changes in ambient temperature, a temperature rise caused by self-heating, and the like. Accordingly, depending on the level of the detection accuracy of a current and the accuracy of a unit time, errors are accumulated gradually in an alternating succession of charging and discharging. Thus, in order to display the remaining capacity of the battery 21 by using the current integrated capacity, it is necessary to correct these accumulated errors.

In view of the above, Patent Document 1 discloses a method for correcting the accumulated errors when the battery remaining capacity is displayed in minutes by using the current integration technique. According to the method disclosed in Patent Document 1, with the use of the fact that there is a high correlation between a battery voltage and a remaining capacity in a portion where the battery voltage changes abruptly, the integration error caused by current integration is corrected by using the remaining capacity obtained from a change in the battery voltage.

As shown in FIG. 10B, in the case of a battery such as a lithium ion battery having characteristics that a battery voltage is in a relatively flat curve over an entire discharge curve, the voltage changes flatly when the remaining capacity is about 50% (timing t82 in FIG. 10B), for example. Accordingly, it is difficult to obtain a correlation between the voltage value and the capacity value, resulting in difficulty in measuring the remaining capacity value accurately from the voltage value. In contrast, when the remaining capacity is close to zero, the voltage changes abruptly (timing t83 in FIG. 10B). Accordingly, there is a high correlation between the voltage value and the capacity value. In other words, in the region where the voltage changes abruptly, when the voltage is determined, the remaining capacity value (mAh) corresponding to that voltage also is found accurately. In this case, around the timing t83, when the voltage value of the battery 21 is determined, then the remaining capacity value (mAh) corresponding to that voltage value also is found accurately.

With the use of these characteristics, when the voltage value corresponding to a portion where the remaining capacity is dose to zero is reached, the current integrated capacity value (mAh) at this time is replaced with the remaining capacity value (mAh) obtained from the voltage value, thereby canceling the accumulated errors caused by current integration. In this manner, the current integrated capacity value (mAh) can be corrected.

### Patent Document 1: JP 5 (1993)-87896 A

### DISCLOSURE OF INVENTION

### Problem to be Solved by the Invention

However, according to the above-described configuration, since the current integrated capacity value is corrected while the battery is discharged (in particular, when the remaining capacity becomes small), a phenomenon occurs around the timing of the correction, in which the value (lifetime) displayed in the display portion 25 becomes discontinuous with respect to the passage of actual time. More specifically, there occurs a phenomenon (hereinafter, referred to as a “standstill phenomenon”) in which the value displayed in the display portion 25 does not decrease with the passage of actual time, or a phenomenon (hereinafter, referred to as a “skip phenomenon”) in which the value displayed in the display portion 25 suddenly decreases sharply and discontinuously with respect to the passage of actual time. In FIG. 10A, an arrow Z1 represents a usual direction of change in which the value decreases at a constant rate, an arrow Z2 represents a direction of change when the standstill phenomenon occurs, and an arrow Z3 represents a direction of change when the slip phenomenon occurs.

The discontinuity in the remaining capacity display value occurs in the process in which the current integrated capacity value (mAh) approaches an ideal value (i.e., an actual remaining current capacity of the battery) as a result of correcting the error by replacing the displayed value calculated by using the current integrated capacity value (mAh) obtained so far with a value calculated by using the remaining capacity value (mAh) obtained from the voltage value when the remaining capacity of the battery 21 is running out. This is shown in FIGS. 11A and 11B. With reference to the figures, a description will be given of a difference in a correction method depending on the direction of change of the display value obtained as a result of correcting the error in the current integrated capacity value (mAh).

In FIGS. 11A and 11B, C11 denotes the remaining capacity display value displayed in the display portion 25, and C12 denotes a remaining capacity actual value representing an actual remaining capacity. The figures show an exemplary case where the remaining capacity display value is corrected at a timing t91 when the current integrated capacity value decreases to 10% of its initial value.

As shown in FIG. 11A, when the remaining capacity actual value C12 is higher than the remaining capacity display value C11, the standstill phenomenon occurs at the timing t91 in which the value displayed in the display portion 25 stops decreasing even with the passage of time of discharging the battery 21. Further, as shown in FIG. 11B, when the remaining capacity display value C11 is lower than the remaining capacity actual value C12, the skip phenomenon occurs in which the remaining capacity display value displayed in the display portion 25 sharply decreases at the instant when the remaining capacity display value is corrected at the timing t91. In other words, as shown in FIGS. 11A and 11B, when the remaining capacity display value is corrected when the current integrated capacity value decreases to 10%, either the standstill phenomenon or the skip phenomenon necessarily occurs unless the current integrated capacity value (mAh) is equal to the remaining capacity value (mAh) obtained from the voltage value.

The conventional electronic device assigns the highest priority to using the current integrated capacity charged into the battery totally, and necessarily involves a system with the standstill phenomenon or the skip phenomenon that occurs by correcting the error in the display of the remaining capacity by using the voltage around the final stages of discharging.

However, these phenomena seriously damage the credibility of the display of the battery remaining capacity for a user of the electronic device. Specifically, even after the user of the electronic device recognizes from the remaining capacity display value that decreases smoothly that the battery needs changing, the standstill phenomenon could occur in which the remaining capacity display value suddenly stops decreasing in proportion to the passage of actual time. Further, even after the user of the electronic device recognizes from the remaining capacity display value that the battery can be used continuously a little longer, the skip phenomenon could occur in which the remaining capacity display value suddenly becomes zero or a value close to zero, so that the electronic device stops operating. If the standstill phenomenon or the skip phenomenon occurs frequently, the user may feel anxious when the remaining capacity display value decreases to some extent (in the above example, around 10%).

Consequently, in order to prevent the electronic device in use from becoming inoperative suddenly, the user may replace the battery in use, even though it still has a remaining capacity, with a charged spare battery. As a result, even with the display of the remaining capacity in minutes, the remaining capacity of the battery hardly is used entirely, and full use is not made of the capacity of the battery.

It is an object of the present invention to provide an electronic device, a battery, and a battery remaining capacity display method that allow a remaining capacity display value to decrease properly with the passage of actual time.

### Means for Solving Problem

An electronic device according to the present invention is capable of displaying a remaining capacity of a battery that includes a battery control portion capable of outputting battery information including remaining capacity information. The device includes: a main body control portion that obtains the battery information from the battery control portion, and calculates a remaining capacity actual value representing an actual remaining capacity of the battery based on the battery information; and a display portion that displays the remaining capacity of the battery under the control of the main body control portion. The main body control portion subtracts a correction margin value representing an individual difference of the battery from the remaining capacity actual value so as to calculate a remaining capacity correction value, and controls the display portion so as to display a remaining capacity of zero for a region where the remaining capacity correction value is equal to or smaller than the correction margin value.

A battery according to the present invention can be connected to an electronic device capable of displaying a remaining capacity of the battery. The battery includes a battery control portion capable of outputting battery information including remaining capacity information. The battery control portion can calculate a remaining capacity actual value representing an actual remaining capacity of the battery based on the battery information, and subtracts a correction margin value representing an individual difference of the battery from the remaining capacity actual value so as to calculate a remaining capacity correction value, and displays a remaining capacity of zero in the electronic device for a region where the remaining capacity correction value is equal to or smaller than the correction margin value.

A battery remaining capacity display method according to the present invention is for displaying a remaining capacity of a battery that includes a battery control portion capable of outputting battery information including remaining capacity information. The method includes the steps of obtaining the battery information from the battery control portion, and calculating a remaining capacity actual value representing an actual remaining capacity of the battery based on the battery information; subtracting a correction margin value representing an individual difference of the battery from the remaining capacity actual value so as to calculate a remaining capacity correction value; and displaying a predetermined remaining capacity value continuously when the remaining capacity correction value is equal to or smaller than the correction margin value.

### EFFECTS OF THE INVENTION

According to the present invention, it is possible to display a remaining capacity display value accurately with respect to the passage of actual time.

### BRIEF DESCRIPTION OF DRAWINGS

FIG. 1 is a block diagram showing configurations of an electronic device and a battery according to Embodiment 1.

FIG. 2A is a characteristics diagram showing a change in a current integrated capacity with the passage of time during charging.

FIG. 2B is a characteristics diagram showing a change in a current integrated capacity with the passage of time during discharging.

FIG. 3A is a characteristics diagram showing a change in an uncorrected display value of a lifetime with the passage of time.

FIG. 3B is a characteristics diagram showing a change in a corrected display value of a lifetime with the passage of time.

FIG. 4A is a characteristics diagram showing a change in an uncorrected display value of a lifetime with the passage of time.

FIG. 4B is a characteristics diagram showing a change in an uncorrected display value of a lifetime with the passage of time.

FIG. 5A is a characteristics diagram showing a change in a current integrated capacity with the passage of time during initial charging.

FIG. 5B is a characteristics diagram showing a change in a current integrated capacity with the passage of time during initial discharging.

FIG. 5C is a characteristics diagram showing a change in a current integrated capacity with the passage of time during subsequent charging.

FIG. 5D is a characteristics diagram showing a change in a current integrated capacity with the passage of time during subsequent discharging.

FIG. 6A is a flowchart illustrating a flow of an operation during charging.

FIG. 6B is a flowchart illustrating a flow of an operation during discharging.

FIG. 7 is a block diagram showing configurations of an electronic device and a battery according to Embodiment 2.

FIG. 8 is a block diagram showing configurations of a conventional electronic device and a conventional battery.

FIG. 9A is a characteristics diagram showing a change in a current integrated capacity with the passage of time during charging.

FIG. 9B is a characteristics diagram showing a change in a current integrated capacity with the passage of time during discharging.

FIG. 10A is a characteristics diagram showing a change in a current integrated capacity rate with the passage of time.

FIG. 10B is a characteristics diagram showing a change in a battery voltage with the passage of time during discharging.

FIG. 11A is a characteristics diagram showing a change in a current integrated capacity corrected by a conventional correction method, with the passage of time.

FIG. 11B is a characteristics diagram showing a change in a current integrated capacity corrected by a conventional correction method, with the passage of time.

### DESCRIPTION OF THE INVENTION

An electronic device according to the present invention is capable of displaying a remaining capacity of a battery that includes a battery control portion capable of outputting battery information including remaining capacity information. The device includes: a main body control portion that obtains the battery information from the battery control portion, and calculates a remaining capacity actual value representing an actual remaining capacity of the battery based on the battery information; and a display portion that displays the remaining capacity of the battery under the control of the main body control portion. The main body control portion subtracts a correction margin value representing an individual difference of the battery from the remaining capacity actual value so as to calculate a remaining capacity correction value, and controls the display portion so as to display a remaining capacity of zero for a region where the remaining capacity correction value is equal to or smaller than the correction margin value. With this configuration, it is possible to avoid the occurrence of a skip phenomenon and a standstill phenomenon in the display of the remaining capacity of the battery in the electronic device, so that the remaining capacity can be displayed accurately with respect to the passage of actual time.

Note here that the “individual difference of a plurality of the batteries” as described above refers to a difference in type and/or blending amount etc. of an electrolyte used in the battery, variations in the electrochemical property of individual batteries, an error in current detection by the battery control portion, an error in counting a unit time, and the like. Further, the “correction margin value” refers to a current capacity value sufficient to accommodate and correct a variation due to the individual difference.

In the electronic device according to the present invention, the main body control portion can turn off a power source of the electronic device when the battery remaining capacity displayed in the display portion becomes zero. With this configuration, even when the battery remaining capacity displayed in the display portion becomes zero, the battery still has a remaining capacity, thereby preventing overdischarge of the battery.

Further, in a state where the remaining capacity displayed in the display portion is zero, when the remaining capacity actual value is larger than the correction margin value, the main body control portion can add a capacity value representing a difference between the remaining capacity actual value and the correction margin value to the remaining capacity information at the start of subsequent charging.

On the other hand, in a state where the remaining capacity displayed in the display portion is zero, when the remaining capacity actual value is smaller than the correction margin value, the main body control portion can subtract the capacity value representing the difference between the remaining capacity actual value and the correction margin value from the remaining capacity information at the start of subsequent charging. With this configuration, it is possible to display an appropriate remaining capacity value when the battery is fully charged to an appropriate capacity value during subsequent charging. For example, since an appropriate capacity can be charged into the battery, it is possible to avoid overdischarge of the battery during subsequent discharging and also to reduce the charging time.

A battery according to the present invention can be connected to an electronic device capable of displaying a remaining capacity of the battery. The battery includes a battery control portion capable of outputting battery information including remaining capacity information. The battery control portion can calculate a remaining capacity actual value representing an actual remaining capacity of the battery based on the battery information, and subtracts a correction margin value representing an individual difference of the battery from the remaining capacity actual value so as to calculate a remaining capacity correction value, and displays a remaining capacity of zero in the electronic device for a region where the remaining capacity correction value is equal to or smaller than the correction margin value. With this configuration, it is possible to control the remaining capacity on a battery side, which negates the need to control the remaining capacity of the battery in the electronic device, thereby simplifying the configuration of the electronic device.

Based on the above-described configuration, the battery of the present invention may have the following various aspects.

The battery according to the present invention further can include a display portion capable of displaying the remaining capacity of the battery. The battery control portion can display the remaining capacity of the battery in the display portion based on the remaining capacity correction value. With this configuration, it is possible to check a remaining lifetime not only via the electronic device but also on the battery side, thereby increasing user convenience. In addition, it is possible to check a lifetime of the battery available in the electronic device only by mounting the battery on the electronic device. Thus, during charging with a charger, main body charging by which the battery is charged while being mounted on the electronic device, and the like, it is possible to check on the progress of charging only by visually recognizing the display portion on the battery side, resulting in an increase in the flexibility in checking the lifetime of the battery.

Further, in a state where zero is displayed in the battery side display portion, when the remaining capacity actual value is larger than the correction margin value, the battery control portion can add a capacity value representing a difference between the remaining capacity actual value and the correction margin value to the remaining capacity information at the start of subsequent charging. In a state where zero is displayed in the battery side display portion, when the remaining capacity actual value is smaller than the correction margin value, the battery control portion can subtract the capacity value representing the difference between the remaining capacity actual value and the correction margin value from the remaining capacity information at the start of subsequent charging. With this configuration, it is possible to charge an appropriate capacity into the battery. For example, it is possible to avoid overcharge of the battery and also to reduce the charging time.

A battery remaining capacity display method according to the present invention is for displaying a remaining capacity of a battery that includes a battery control portion capable of outputting battery information including remaining capacity information. The method includes the steps of obtaining the battery information from the battery control portion, and calculating a remaining capacity actual value representing an actual remaining capacity of the battery based on the battery information; subtracting a correction margin value representing an individual difference of the battery from the remaining capacity actual value so as to calculate a remaining capacity correction value; and displaying a predetermined remaining capacity value continuously when the remaining capacity correction value is equal to or smaller than the correction margin value. With this method, it is possible to avoid the occurrence of a skip phenomenon and a standstill phenomenon in the display of the remaining capacity of the battery in an electronic device, so that the remaining capacity can be displayed accurately with respect to the passage of actual time.

In the battery remaining capacity display method according to the present invention, when the displayed remaining capacity value becomes zero, a power source of an electronic device connected to the battery may be turned of With this method, even when the battery remaining capacity displayed in a display portion becomes zero, the battery still has a remaining capacity, thereby preventing overdischarge of the battery.

Further, in the battery remaining capacity display method according to the present invention, in a state where the displayed remaining capacity value is zero, when the remaining capacity actual value is larger than the correction margin value, a capacity value representing a difference between the remaining capacity actual value and the correction margin value can be added to the remaining capacity information at the start of subsequent charging.

On the other hand, in a state where the displayed remaining capacity value is zero, when the remaining capacity actual value is smaller than the correction margin value, the capacity value representing the difference between the remaining capacity actual value and the correction margin value may be subtracted from the remaining capacity information at the start of subsequent charging. With this method, it is possible to display an appropriate remaining capacity value when the battery is fully charged to an appropriate capacity value during subsequent charging. For example, since an appropriate capacity can be charged into the battery, it is possible to avoid overdischarge of the battery during subsequent discharging and also to reduce the charging time.

### Embodiment 1

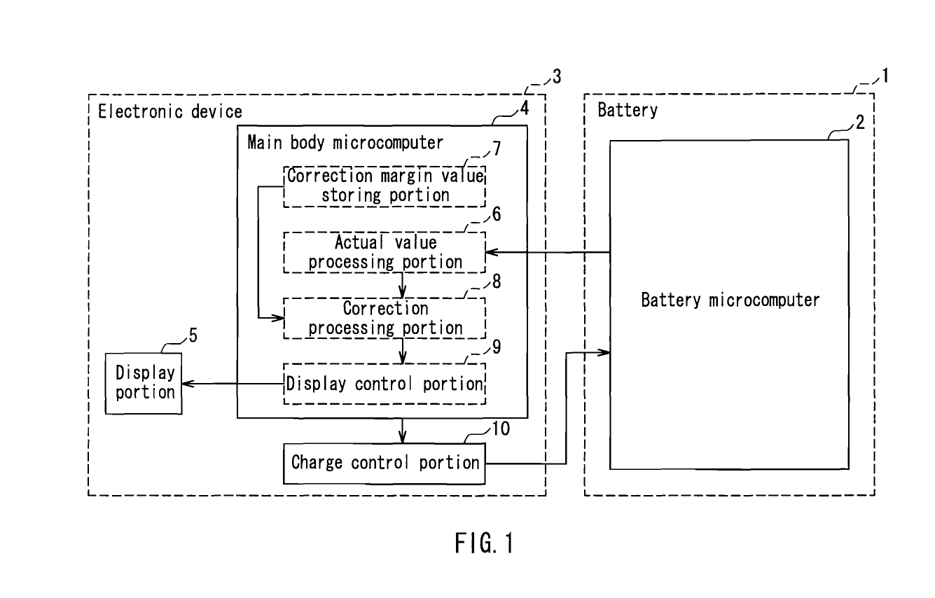

FIG. 1 is a block diagram showing a configuration of an embodiment of an electronic device having the capability of displaying a battery remaining capacity. As shown in FIG. 1, a battery 1 is formed of a secondary battery, such as a lithium ion battery, that can be charged and discharged. The battery 1 has a battery microcomputer 2.

The battery microcomputer 2 processes information from the battery 1. The information to be processed by the battery microcomputer 2 includes a voltage, a remaining capacity, a current, a remaining capacity rate, etc. of the battery 1. The battery microcomputer 2 is shown as an example of a battery control portion, and the battery control portion, which is not necessarily required to be realized by a microcomputer, may have another form as long as it can at least process the information from the battery 1.

An electronic device 3 is formed of a device, such as a digital camera, a video camera, and a mobile phone terminal, that is operated by electric power supplied by the battery 1. In the present embodiment, a description will be given taking a video camera as an example. The electronic device 3 includes a main body microcomputer 4. The electronic device 3 may include other microcomputers for controlling various operations of the electronic device 3 in addition to the main body microcomputer 4. Alternatively, the main body microcomputer 4 may have the capability of controlling various operations of the electronic device 3.

The main body microcomputer 4 processes the information on the battery 1 sent from the battery microcomputer 2, and displays a remaining capacity in a display portion 5. The main body microcomputer 4 includes an actual value processing portion 6, a correction margin value storing portion 7, a correction processing portion 8, and a display control portion 9. Specific operations of the respective portions will be described later. The main body microcomputer 4 is shown as an example of a main body control portion, and the main body control portion, which is not necessarily required to be realized by a microcomputer, may have another form as long as it can control at least the display of the battery remaining capacity.

The display portion 5 can display the remaining capacity under the control of the main body microcomputer 4. The display portion 5, which corresponds to a liquid crystal display generally mounted on a digital camera, a video camera, and the like, can display an image and various information as well as the battery remaining capacity. The display portion 5 may be realized by another display element such as an organic EL display as long as it can display at least the information such as the battery remaining capacity.

The main body microcomputer 4 stores the remaining capacity information of the battery 1 obtained from the battery microcomputer 2 in the actual value processing portion 6. Further, the main body microcomputer 4 reads a correction margin value stored in the correction margin value storing portion 7. Note here that the correction margin value refers to a remainder prepared previously by subtracting a correction portion required to accommodate a variable factor due to an individual difference of the battery 1. This value is kept previously during charging as a margin for filling a gap between a displayed battery remaining capacity and an actual battery remaining capacity when a displayed remaining lifetime obtained by integration disagrees with an ideal value due to an error caused by the individual difference.

The correction processing portion 8 subtracts the correction margin value from a remaining capacity actual value stored in the actual value processing portion 6, thereby calculating a remaining capacity correction value.

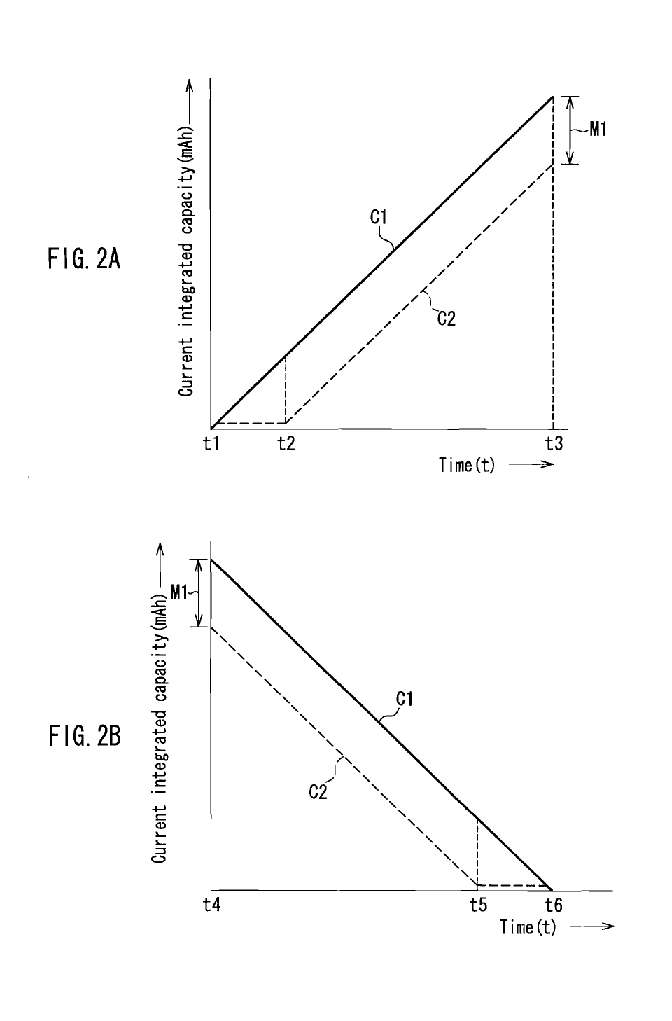

FIG. 2A shows a change in a current integrated capacity with the passage of time during the charging of the battery 1. FIG. 2B shows a change in a current integrated capacity with the passage of time during the discharging of the battery 1. C1 denotes the remaining capacity actual value, and C2 denotes the remaining capacity correction value.

As shown in FIG. 2A, during the charging of the battery 1, even when the remaining capacity actual value C1 of the battery 1 increases after the start of charging from a timing t1, the remaining capacity correction value C2 does not increase for a certain time as shown in a period from t1 to t2, since the remaining capacity correction value is calculated previously by subtracting the correction margin value from the remaining capacity actual value in an early stage. When the battery is charged continuously, the remaining capacity correction value C2 starts increasing from a timing t2. When the charging is continued further, the battery is fully charged at a timing t3. At this time, the remaining capacity correction value C2 is lower than the remaining capacity actual value C1 by a correction margin value M1.

As shown in FIG. 2B, the discharging of the battery 1 is started (timing 4) in a state where the remaining capacity is displayed based on the remaining capacity correction value C2 that is lower than the remaining capacity actual value C1 by the correction margin value M1. The remaining capacity correction value C2 is always lower than the remaining capacity actual value C1 during the discharging of the battery 1, and becomes zero (timing 5) earlier than the remaining capacity actual value C1 when the battery 1 is discharged continuously. When the discharging of the battery 1 is continued further, the remaining capacity displayed based on the remaining capacity correction value C2 remains to be zero, although it is actually possible to supply electric power to the electronic device 3 until a timing t6 when the battery is totally discharged.

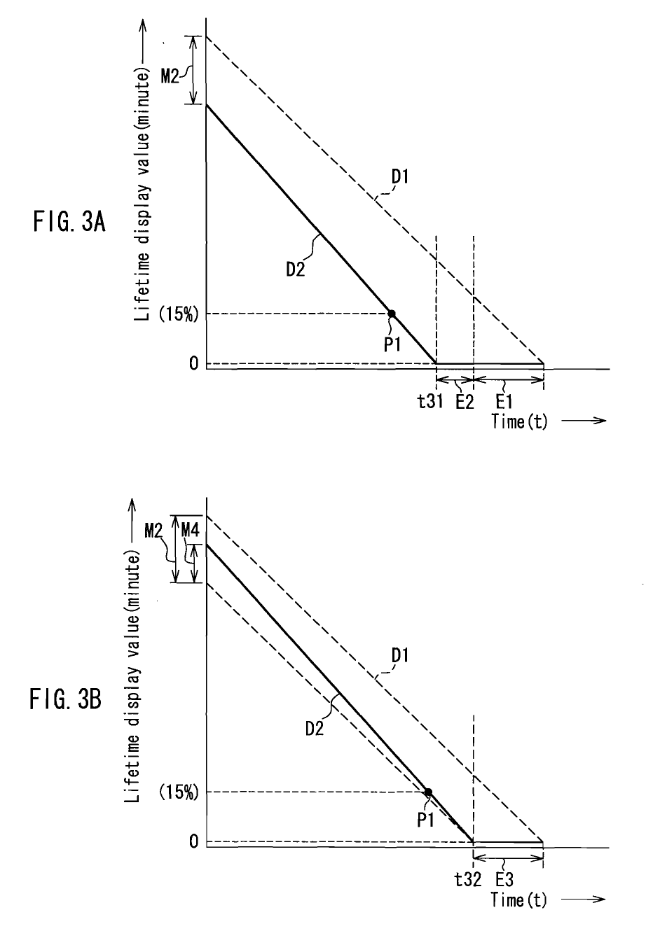

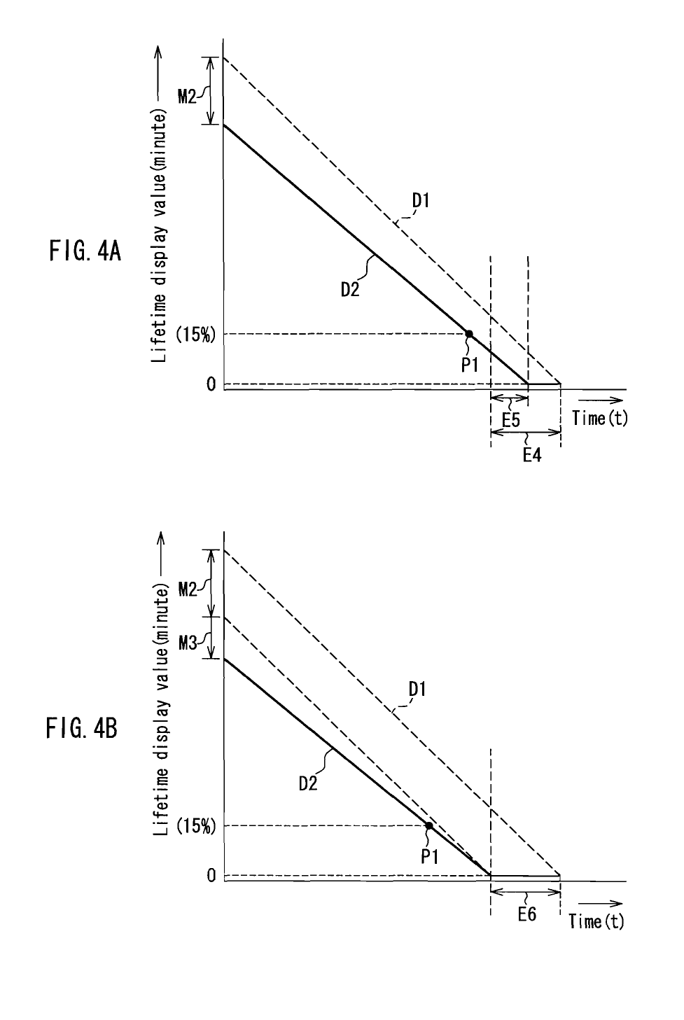

FIGS. 3A and 4A show changes in a display value of a lifetime with the passage of time during the discharging of the battery 1. FIGS. 3B and 4B show changes in a display value of a lifetime with the passage of time during discharging subsequent to the discharging with the characteristics shown in FIGS. 3A and 4A. In FIGS. 3A, 3B, 4A, and 4B, D1 denotes a display ideal value, D2 denotes the remaining capacity correction value, and M2 denotes the correction margin value.

As shown in FIG. 3A, when the remaining capacity correction value D2 changes downward as compared with a line parallel to the display ideal value D1, the displayed lifetime decreases more steeply than the slope of the display ideal value D1. As a result, the remaining lifetime displayed in the display portion 5 is always smaller than an originally estimated value. When the displayed lifetime becomes zero (timing t31), the discharging of the battery is finished with an originally estimated remaining time E1 corresponding to the correction margin value M2 as well as a time E2 left. In this case, when the displayed lifetime becomes zero, a current integrated capacity value M4 corresponding to a portion exceeding the correction margin value M2 of the battery remaining capacity is calculated so as to be added to the remaining capacity correction value at the start of subsequent charging, thereby increasing an available current integrated capacity of the battery 1. Consequently, as shown in FIG. 3B, the discharging of the battery 1 is started from a value obtained by adding the current integrated capacity value M4 to the correction margin value M2. In the example shown in FIGS. 3A and 3B, since the remaining capacity correction value D2 changes downward as compared with the line parallel to the display ideal value D1, the charging operation of the battery 1 can be improved so that only the originally estimated correction margin value M2 is left unused (i.e., a time E3 corresponding to the correction margin value M2 is left) when the displayed lifetime becomes zero (t32). Note here that E3 is equal to E1.

On the other hand, as shown in FIG. 4A, when the remaining capacity correction value D2 changes upward as compared with the line parallel to the display ideal value D1, the displayed lifetime decreases more gently than the slope of the display ideal value D1. As a result, the lifetime displayed in the display portion 5 is always larger than an originally estimated value. At this time, a current capacity supplied from the battery 1 changes while a portion corresponding to the correction margin value M2 that is kept previously by subtraction from the remaining capacity correction value is consumed. As a result, the portion corresponding to the correction margin value 2 can be left unused until the displayed lifetime becomes zero as a whole. Therefore, it is possible to avoid a failure where the remaining capacity of the battery runs out while the display shows capacity is still remaining.

In this case, during the initial discharging shown in FIG. 4A, the originally estimated correction margin value M2 is consumed to some extent. Accordingly, the displayed lifetime becomes zero a time E5 earlier than a remaining time E4 corresponding to the correction margin value M2. In this case, a deficiency value M3 representing a deficiency in the current integrated capacity corresponding to the time E5 is calculated. Then, as shown in FIG. 4B, the deficiency value M3 in the current integrated capacity is subtracted previously from the remaining capacity correction value including the correction margin value M2 at the start of subsequent charging, so that the correction margin value of the battery 1 can be made equal to an originally estimated value. In other words, during subsequent discharging, a remaining time E6 when the lifetime becomes zero can be made equal to the remaining time E4 that originally has been estimated to be left when the discharging is finished.

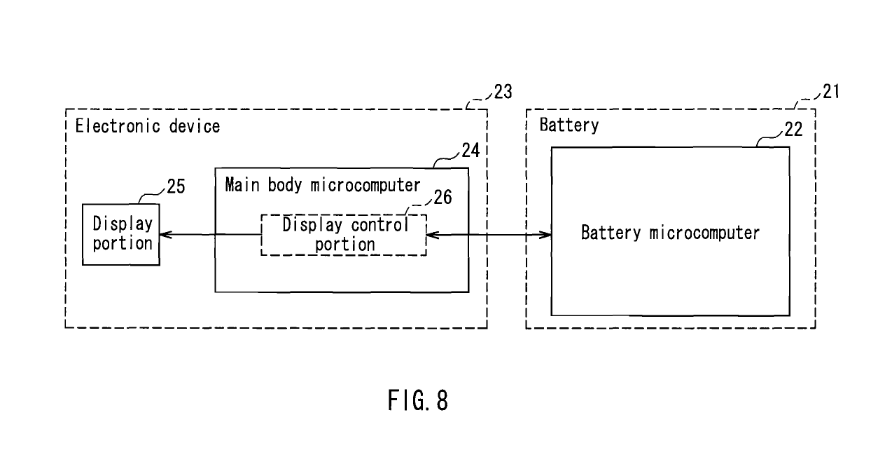

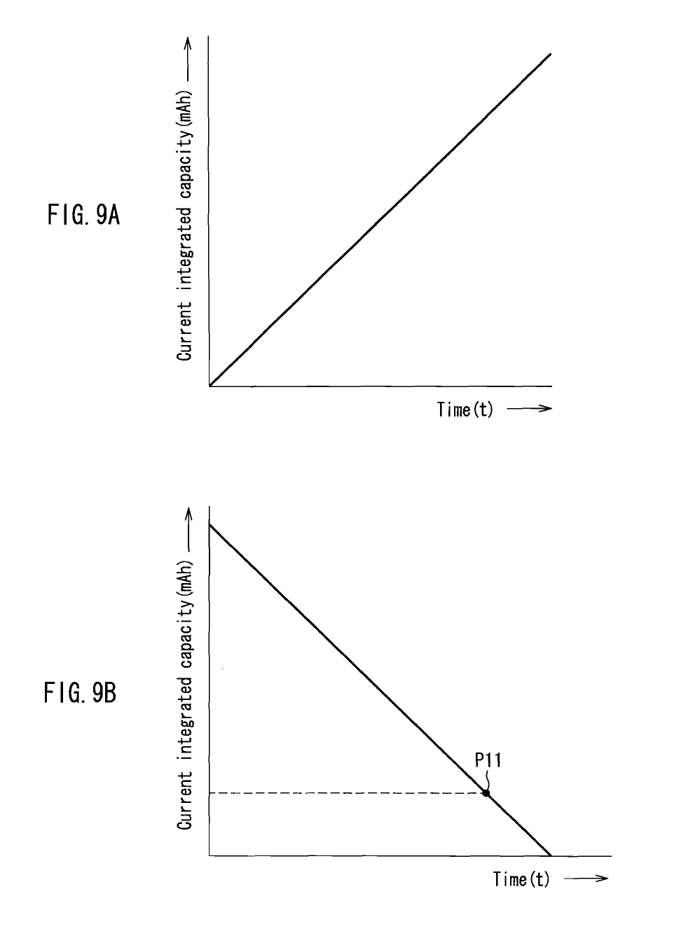

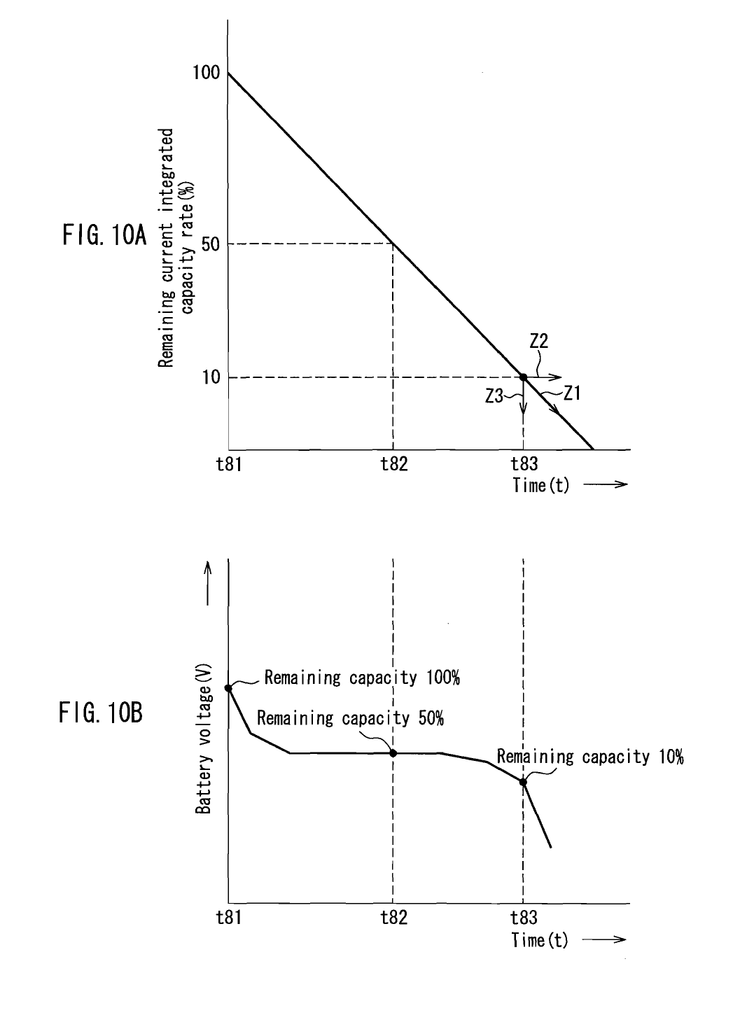

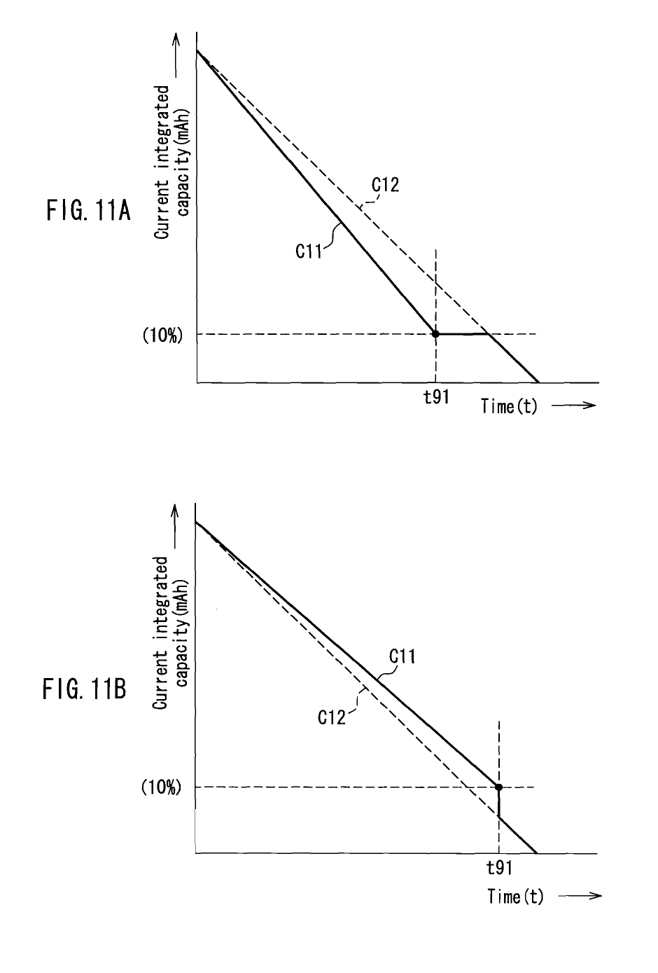

A point P1 represents a timing at which an error in current integration is corrected. In the present embodiment, the correction is performed when the remaining capacity of the remaining capacity actual value is 15%. At the point P1, a difference between a remaining capacity value obtained from a discharge voltage curve (see FIG. 8B) and a remaining capacity value obtained from current integration is calculated, and a correction value of a current integrated value is calculated based on the difference. The correction value is not reflected on the remaining capacity correction value immediately, but is subtracted or added from/to the remaining capacity correction value during subsequent charging, thereby correcting the current integrated value corresponding to the remaining capacity correction value. With this configuration, it is possible to assure the accuracy of the displayed remaining capacity while avoiding the occurrence of the standstill phenomenon and/or the skip phenomenon in the value, and to consume the actual remaining capacity of the battery 1 efficiently.

In the present embodiment, the description has been given taking as an example the case where the correction processing is performed when the remaining capacity of the remaining capacity actual value is 15%. However, the point at which the correction processing is performed actually is not fixed to 15%. The same effect as that in the present embodiment can be achieved as long as the point is before the time when the remaining capacity correction value becomes zero, and the remaining capacity estimated from the discharge voltage curve of the battery 1 can be calculated accurately. Conversely, when the correction point is higher, there is a tendency that a user is allowed to perform correction more easily, but at the same time, the remaining capacity estimated from the discharge voltage curve of the battery 1 is calculated with less accuracy. On the other hand, when the correction point is lower, there could be a tendency that the remaining capacity estimated from the discharge voltage curve of the battery 1 is calculated with more accuracy, but it becomes difficult to perform correction because the user becomes more likely to replace the battery in use with another battery or charge the battery in use before the point is reached.

Next, a specific operation of correcting the current integrated capacity will be described.

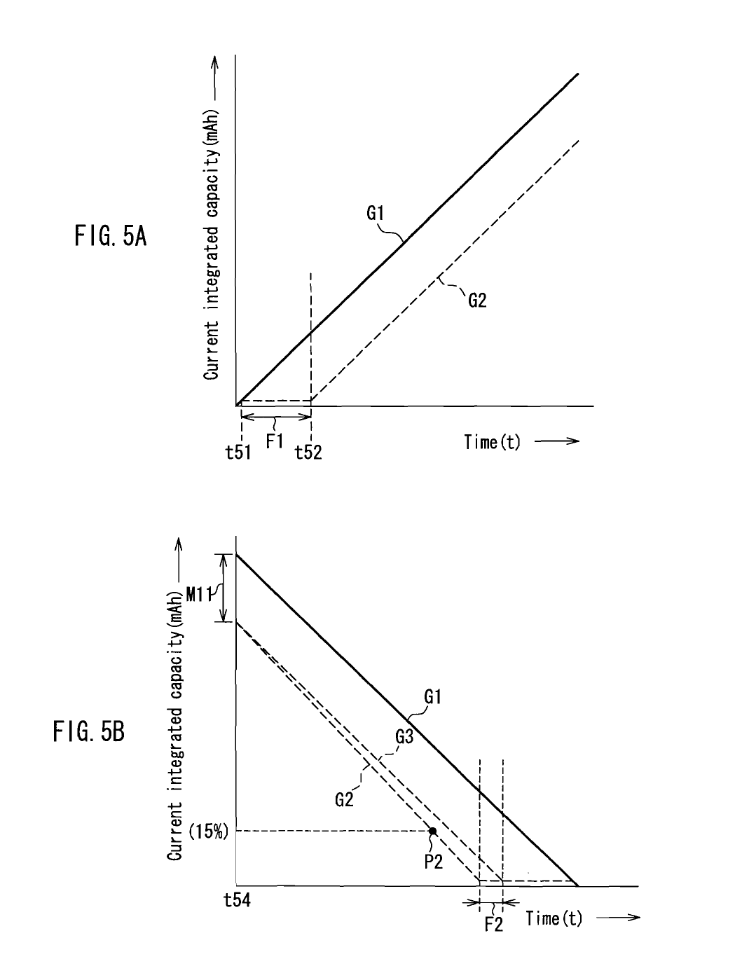

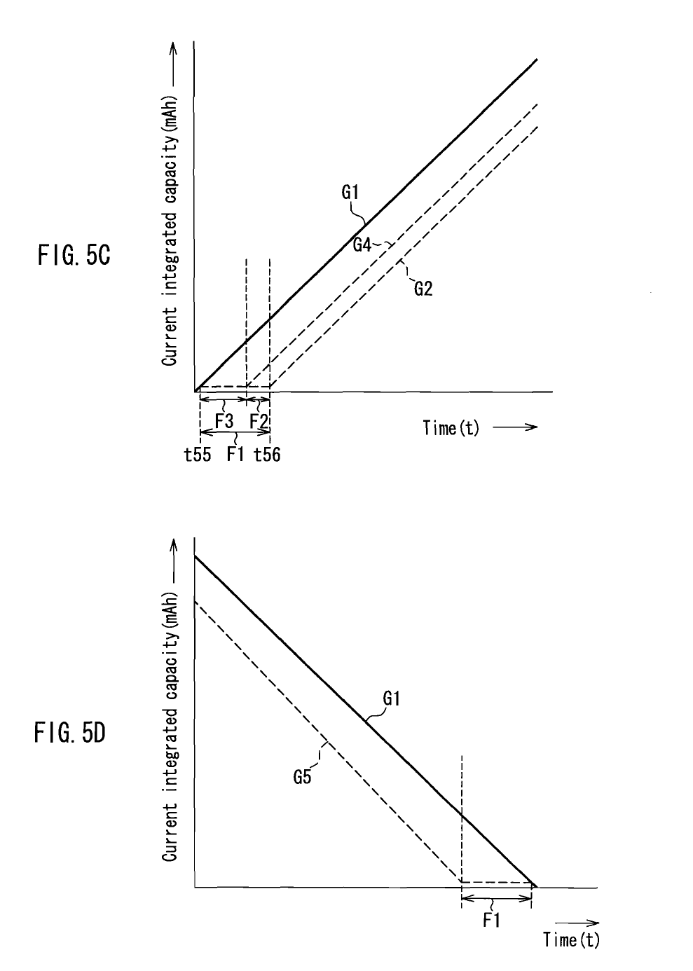

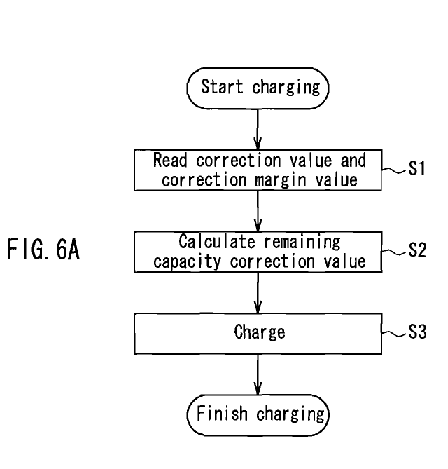

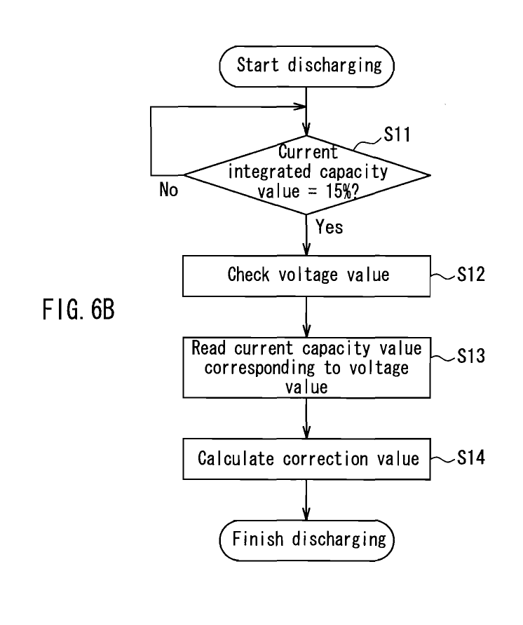

FIGS. 5A to 5D show changes in the current integrated capacity with the passage of time during the charging and discharging of the battery 1. FIG. 5A shows characteristics during initial charging, FIG. 5B shows characteristics during initial discharging, FIG. 6A shows characteristics during subsequent charging, and FIG. 6B shows characteristics during subsequent discharging. Further, FIG. 6A shows an operation during the charging of the battery 1. FIG. 6B shows an operation during the discharging of the battery 1. A specific configuration of a battery remaining capacity display device is shown in FIG. 1.

First, as shown in FIG. 5A, when the battery 1 is charged, a correction value calculated during previous discharging and a correction margin value stored in the correction margin value storing portion 7 are read at a timing t51 (S1 in FIG. 6A). Here, since the characteristics shown in FIG. 5A are those during initial charging of the battery 1, there is no correction value calculated during previous discharging, and thus only the correction margin value is read.

Then, the correction processing portion 8 subtracts the correction margin value (corresponding to a period F1) from a remaining capacity actual value G1 so as to calculate a remaining capacity correction value G2 (S2 in FIG. 6A). Thereafter, the display control portion 9 starts displaying a battery remaining capacity in the display portion 5 based on the remaining capacity correction value G2 calculated by the correction processing portion 8. At this time, the battery remaining capacity displayed in the display portion 5 is zero because charging is not yet started.

Then, the main body microcomputer 4 controls a charge control portion 10 to start charging the battery 1 (S3 in FIG. 6A). After the start of charging, during the period F1 from t51 to t52, the display portion 5 displays that the battery remaining capacity is zero. After the timing t52, the battery remaining capacity is displayed in accordance with an increase in the current integrated capacity. When the current integrated capacity reaches a predetermined value, the main body microcomputer 4 determines that the battery 1 is fully charged, and controls the charge control portion 10 to stop the charging operation.

Next, as shown in FIG. 5B, the discharging of the battery 1 is started. During discharging, the current integrated capacity decreases according to characteristics shown by G1, while the remaining capacity correction value decreases according to characteristics shown by G2. When the remaining capacity correction value G2 decreases to 15% of the current integrated capacity of full charge (S11 in FIG. 6B), the main body microcomputer 4 requires the battery microcomputer 2 to provide a current capacity value of the battery 1. At the request of the main body microcomputer 4, the battery microcomputer 2 detects a voltage value of the battery 1 at this time (S12 in FIG. 6B), and sends a current capacity value corresponding to the detected voltage value to the main body microcomputer 4 (S13 in FIG. 6B). Here, the current capacity value may be calculated by a predetermined formula based on the voltage value, or alternatively may be read from a correspondence table between the voltage value and the current capacity value prepared previously.

Then, the main body microcomputer 4 calculates a correction value F2 representing a difference between the current capacity value G2 obtained from the battery microcomputer 2 and an ideal value G3 (S14 in FIG. 6B).

Next, during subsequent charging shown in FIG. 5C, the correction value calculated during the previous discharging (see FIG. 5B) and the correction margin value stored in the correction margin value storing portion 7 are read (S1 in FIG. 6A).

Then, the correction processing portion 8 subtracts a difference value F3 between the correction margin value (corresponding to the period F1) and the correction value (corresponding to the period F2) from the remaining capacity actual value G1 so as to calculate a remaining capacity correction value G4 (S2 in FIG. 6A). After that, the display control portion 9 starts displaying a battery remaining capacity in the display portion 5 based on the remaining capacity correction value G4 calculated by the correction processing portion 8. At this time, the battery remaining capacity displayed in the display portion 5 is zero because charging is not yet started.

Then, the main body microcomputer 4 controls the charge control portion 10 to start charging the battery 1 (S3 in FIG. 6A). After the start of charging, during the period F3, the display portion 5 displays that the battery remaining capacity is zero. After the period F3, the battery remaining capacity is displayed in accordance with an increase in the current integrated capacity. When the current integrated capacity reaches a predetermined value, the main body microcomputer 4 determines that the battery 1 is fully charged, and controls the charge control portion 10 to stop the charging operation.

Next, as shown in FIG. 5D, the discharging of the battery 1 is started. During discharging, the current integrated capacity decreases according to characteristics shown by G1, while the remaining capacity correction value decreases according to characteristics shown by G5. When the remaining capacity correction value G5 decreases to 15% of the current integrated capacity of full charge (S11 in FIG. 6B), the main body microcomputer 4 requires the battery microcomputer 2 to provide a current capacity value of the battery 1. At the request of the main body microcomputer 4, the battery microcomputer 2 detects a voltage value of the battery 1 at this time (S12 in FIG. 6B), and sends a current capacity value corresponding to the detected voltage value to the main body microcomputer 4 (S13 in FIG. 6B). Here, the current capacity value may be calculated by a predetermined formula based on the voltage value, or alternatively may be read from a correspondence table between the voltage value and the current capacity value prepared previously.

As shown in FIG. 5D, since the remaining capacity correction value is corrected during previous discharging (in the present embodiment, the initial charging), the remaining capacity correction value G5 can agree with the ideal value G3.

As described above, according to the present embodiment, during the discharging of the battery 1, when the current integrated capacity decreases to a predetermined value, the display value of the battery remaining capacity is corrected based on the remaining capacity correction value, thereby suppressing the occurrence of the skip phenomenon and the standstill phenomenon. Therefore, it is possible to decrease the display value of the battery remaining capacity properly with the passage of actual time.

### Embodiment 2

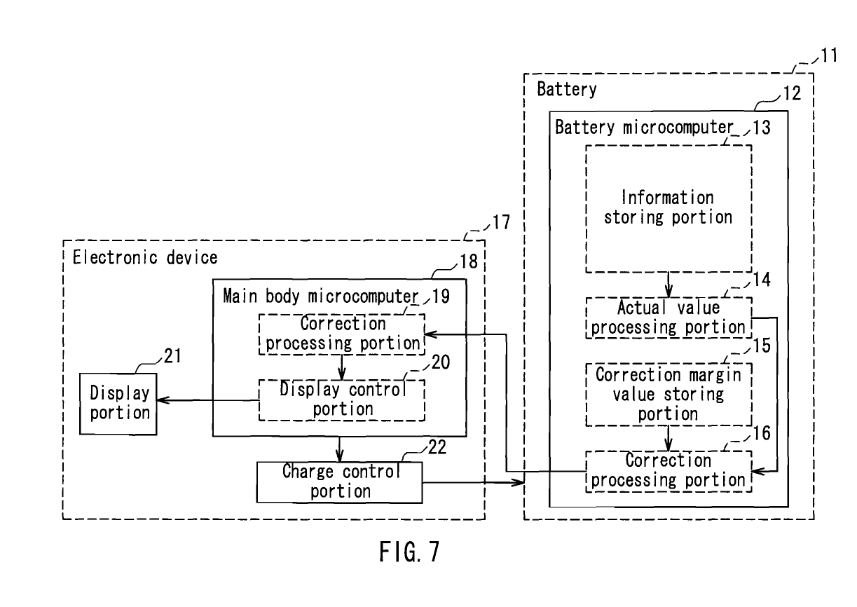

FIG. 7 shows a configuration of an electronic device according to Embodiment 2. The configuration shown in Embodiment 2 is different from that in Embodiment 1 in that a correction margin value storing portion and the like are provided in a battery microcomputer 12 rather than a main body microcomputer. Accordingly, a display value is corrected on a battery 11 side in the present embodiment, while the display value is corrected in the electronic device in Embodiment 1.

More specifically, the battery 11 includes the battery microcomputer 12, and an electronic device 17 includes a main body microcomputer 18, a display portion 21, and a charge control portion 22. The battery microcomputer 12 includes an information storing portion 13, an actual value processing portion 14, a correction margin value storing portion 15, and a correction processing portion 16. The main body microcomputer 18 includes a correction processing portion 19 and a display control portion 20. The respective portions are operated in the same manners as those in Embodiment 1, and thus detailed descriptions thereof will not be repeated.

In the present embodiment, a correction margin value is managed on a battery microcomputer 12 side, and a result of subtraction is supplied to the main body microcomputer 18 as remaining capacity information. Consequently, the correction processing portion 19 in the main body microcomputer 18 receives a value that already has been corrected by subtracting the correction margin value from a remaining capacity actual value. As in Embodiment 1, the main body microcomputer 18 turns off a power source of the electronic device 17 automatically when the battery is discharged until the display portion 21 displays that a battery remaining capacity is zero.

As described above, according to the present embodiment, during the discharging of the battery 11, when a current integrated capacity decreases to a predetermined value, the electronic device is controlled so that a display value of the battery remaining capacity is corrected based on a remaining capacity correction value, thereby suppressing the occurrence of the skip phenomenon and the standstill phenomenon. Therefore, it is possible to decrease the display value of the battery remaining capacity properly with the passage of actual time.

In Embodiments 1 and 2, the battery remaining capacity is displayed in the display portion mounted on the electronic device. However, the display portion may be provided in the battery, so that the battery remaining capacity is displayed therein, which results in the same effect as that in the present embodiments.

Further, in Embodiments 1 and 2, the battery remaining capacity displayed based on the remaining capacity correction value at the start of charging is zero. However, the value to be displayed is not limited to zero as long as at least a predetermined value can be displayed continuously for a predetermined period. For example, in the case of starting charging with the battery remaining capacity left, the remaining capacity correction value at the start of charging may be displayed continuously, which results in the same effect as that in the present embodiments.

### INDUSTRIAL APPLICABILITY

The electronic device and the battery remaining capacity display method of the present invention can be applied widely to mobile devices in general that use a battery as a power source. Further, the battery and the battery remaining capacity display method of the present invention is useful as/for a secondary battery widely applied to mobile devices in general.

1. An electronic device capable of displaying a remaining capacity of a battery that comprises a battery control portion capable of outputting battery information including remaining capacity information, the device comprising:
a main body control portion that obtains the battery information from the battery control portion, and calculates a remaining capacity actual value representing an actual remaining capacity of the battery based on the battery information; and
a display portion that displays the remaining capacity of the battery under the control of the main body control portion,
wherein the main body control portion subtracts a correction margin value that accommodates a variation due to an individual difference of the battery from the remaining capacity actual value so as to calculate a remaining capacity correction value, and
the main body control portion calculates the remaining capacity of the battery to be displayed in the display portion based on the remaining capacity correction value.

2. The electronic device according to claim 1, wherein the main body control portion turns off a power source of the electronic device when the remaining capacity value displayed in the display portion becomes zero.

3. The electronic device according to claim 1,
wherein in a state where the remaining capacity value displayed in the display portion is zero, when the remaining capacity actual value is larger than the correction margin value, the main body control portion adds a capacity value representing a difference between the remaining capacity actual value and the correction margin value to the remaining capacity information at the start of subsequent charging, and
in a state where the remaining capacity value displayed in the display portion is zero, when the remaining capacity actual value is smaller than the correction margin value, the main body control portion subtracts the capacity value representing the difference between the remaining capacity actual value and the correction margin value from the remaining capacity information at the start of subsequent charging.

4. A battery whose remaining capacity can be displayed, the battery comprising a battery control portion capable of outputting battery information including remaining capacity information,
wherein the battery control portion can calculate a remaining capacity actual value representing an actual remaining capacity of the battery based on the battery information, and subtracts a correction margin value that accommodates a variation due to an individual difference of the battery from the remaining capacity actual value so as to calculate a remaining capacity correction value, and
the battery control portion calculates the remaining capacity of the battery to be displayed in an electronic device based on the remaining capacity correction value.

5. The battery according to claim 4, further comprising a display portion capable of displaying the remaining capacity value,
wherein the battery control portion displays the remaining capacity value in the display portion based on the remaining capacity correction value.

6. The battery according to claim 4,
wherein in a state where the remaining capacity value displayed in the battery side display portion is zero, when the remaining capacity actual value is larger than the correction margin value, the battery control portion adds a capacity value representing a difference between the remaining capacity actual value and the correction margin value to the remaining capacity information at the start of subsequent charging, and
in a state where the remaining capacity value displayed in the battery side display portion is zero, when the remaining capacity actual value is smaller than the correction margin value, the battery control portion subtracts the capacity value representing the difference between the remaining capacity actual value and the correction margin value from the remaining capacity information at the start of subsequent charging.

7. A battery remaining capacity display method for displaying a remaining capacity of a battery that comprises a battery control portion capable of outputting battery information including remaining capacity information, the method comprising the steps of:
obtaining the battery information from the battery control portion, and calculating a remaining capacity actual value representing an actual remaining capacity of the battery based on the battery information;
subtracting a correction margin value that accommodates a variation due to an individual difference of the battery from the remaining capacity actual value so as to calculate a remaining capacity correction value; and
calculating the remaining capacity of the battery to be displayed in a display portion based on the remaining capacity correction value.

8. The battery remaining capacity display method according to claim 7, wherein when the displayed remaining capacity value becomes zero, a power source of an electronic device connected to the battery is turned off.

9. The battery remaining capacity display method according to claim 7,
wherein in a state where the displayed remaining capacity value is zero, when the remaining capacity actual value is larger than the correction margin value, a capacity value representing a difference between the remaining capacity actual value and the correction margin value is added to the remaining capacity information at the start of subsequent charging; and
in a state where the displayed remaining capacity value is zero, when the remaining capacity actual value is smaller than the correction margin value, the capacity value representing the difference between the remaining capacity actual value and the correction margin value is subtracted from the remaining capacity information at the start of subsequent charging.
